(19) United States
(12) Patent Application Publication
(10) Pub. No.: US 2009/0084757 A1
(43) Pub. Date: Apr. 2, 2009

(54) UNIFORMITY CONTROL FOR ION BEAM ASSISTED ETCHING

(76) Inventors: Yuri Erokhin, Georgetown, MA (US); Steven R. Walther, Andover, MA (US); Peter D. Nunan, Monte Sereno, CA (US)

Correspondence Address: Scott Faber, Esq.;Varian Semiconductor Equipment Associates, Inc, 35 Dory Road, Gloucester, MA, 01930, US

(21) Appl. No.: 11/863,886

(22) Filed: Sep. 28, 2007

(51) Int. Cl. C23C 14/00; B44C 1/22

(52) U.S. Cl. 216/66; 204/298.36

(57) ABSTRACT

An approach for providing uniformity control in an ion beam etch is described. In one embodiment, there is a method for providing uniform etching in an ion beam based etch process. In this embodiment, an ion beam is directed at a surface of a substrate. The surface of the substrate is etched with the ion beam. The etching is controlled to attain uniformity in the etch of the substrate. The control attains uniformity as a function of at least one ion beam based parameter selected from a plurality of ion beam based parameters.

### BACKGROUND

This disclosure relates generally to etching with either plasma or energetic ions, and more specifically to providing uniformity control in ion beam etching of a substrate.

Etching with a traditional ion beam etching system typically results in a significant amount of non-uniformity. For example, in a 300 millimeter diameter wafer used in semiconductor wafer processing, non-uniformities generated from a traditional ion beam etching system can typically result in unacceptable variation from the center of the wafer to the edge of the wafer. The variation manifests itself in the electrical performance of the devices fabricated on the wafer. Traditional ion beam etching systems generate a significant amount of non-uniformity because these systems do not have the capability to locally control exposure of the ion beam during the etching of the wafer. These traditional ion beam etching systems can only make changes to global macroscopic variables that do not affect the exposure on the wafer. In particular, traditional ion beam etching systems can only make changes to variables that affect the overall etching process such as the pressure inside the vacuum chamber, the temperature of the wafer during the etching, etc. Changes to these variables will not aid in obtaining a uniform exposure of the wafer during the etching process. Because there is no capability in these traditional ion beam etching systems to make local changes to variables that affect the exposure of the wafers to the ion beam, the wafers will have a significant amount of non-uniformity that manifests itself in the electrical performance of the devices fabricated on the wafer.

### SUMMARY

In a first embodiment, there is a method for providing uniform etching in an ion beam based etch process. In this embodiment, the method comprises providing a substrate; directing an ion beam at a surface of the substrate; etching the surface of the substrate with the ion beam; and controlling the etching to attain uniformity in the etch of the substrate, wherein the controlling attains uniformity as a function of at least one ion beam based parameter selected from a plurality of ion beam based parameters.

In a second embodiment, there is an ion beam etching system. In this embodiment, the ion beam etching system comprises an end station configured to receive a substrate for ion beam etching. An ion beam generator is configured to direct an ion beam into the end station onto the substrate for etching thereof. A controller is configured to ensure that the ion beam source provides uniform etching of the substrate. The controller provides uniform etching as a function of at least one ion beam based parameter selected from a plurality of ion beam based parameters.

In a third embodiment, there is a computer-readable medium storing computer instructions, which when executed by a computer system enables an ion beam etching system to provide uniformity in the etching of a substrate. In this embodiment, the computer instructions comprise: obtaining measurements during the etching of the substrate that relate to at least one ion beam based parameter selected from a plurality of ion beam based parameters; determining whether the measurements are indicative of a uniform etch spatially across the substrate; and adjusting the at least one ion beam based parameter in response to a determination that the measurements are indicative of a non-uniform etch.

### BRIEF DESCRIPTION OF THE DRAWINGS

FIG. 1 shows a schematic block diagram of an ion beam etching system according to one embodiment of this disclosure;

FIG. 2 shows a schematic block diagram of an ion beam etching system according to a second embodiment of this disclosure;

FIG. 3 shows a top view schematic block diagram of an ion implanter that can be incorporated with the ion beam etching systems shown in FIGS. 1 and 2 according to one embodiment of the disclosure; and

FIG. 4 shows a flow chart describing the operation of the ion beam etching systems shown in FIGS. 1 and 2 according to one embodiment of this disclosure.

### DETAILED DESCRIPTION

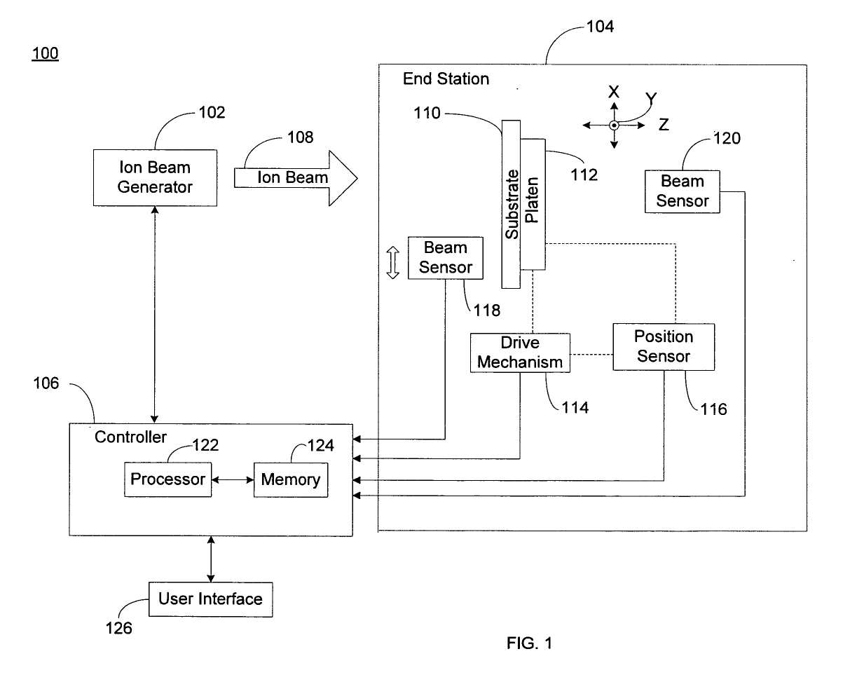

FIG. 1 shows a schematic block diagram of an ion beam etching system 100 according to one embodiment of this disclosure. The ion beam etching system 100 includes an ion beam generator 102, an end station 104, and a controller 106. The ion beam generator 102 generates an ion beam 108 and directs it towards a front surface of a substrate 110. The ion beam 108 is distributed over the front surface of the substrate 110 by beam movement, substrate movement, or by any combination thereof.

The ion beam generator 102 can include various types of components and systems to generate the ion beam 108 having desired characteristics. The ion beam 108 may be a spot beam or a ribbon beam. The spot beam may have an irregular cross-sectional shape that may be approximately circular in one instance. In one embodiment, the spot beam may be a fixed or stationary spot beam without a scanner. Alternatively, the spot beam may be scanned by a scanner for providing a scanned ion beam. The ribbon beam may have a large width/height aspect ratio and may be at least as wide as the substrate 110. The ion beam 108 can be any type of charged particle beam such as an energetic ion beam used to implant the substrate 110.

The end station 104 may support one or more substrates in the path of the ion beam 108 such that ions of the desired species are implanted into the substrate 110. The substrate 110 may be supported by a platen 112 and clamped to the platen 112 by known techniques such as electrostatic wafer clamping. The substrate 110 can take various physical shapes such as a common disk shape. The substrate 110 can be a workpiece such as a semiconductor wafer fabricated from any type of semiconductor material like silicon or any other material that is to be implanted and/or etched using the ion beam 108.

The end station 104 may include a drive system (not illustrated) that physically moves the substrate 110 to and from the platen 112 from holding areas. The end station 104 may also include a drive mechanism 114 that drives the platen 112 and hence the substrate 110 in a desired way. The drive mechanism 114 may include servo drive motors, screw drive mechanisms, mechanical linkages, and any other components as are known in the art to drive the substrate 110 when clamped to the platen 112.

The end station 104 may also include a position sensor 116, which may be further coupled to the drive mechanism 114, to provide a sensor signal representative of the position of the substrate 110 relative to the ion beam 108. Although illustrated as a separate component, the position sensor 116 may be part of other systems such as the drive mechanism 114. Furthermore, the position sensor 116 may be any type of position sensor known in the art such as a position-encoding device. The position signal from the position sensor 116 may be provided to the controller 106.

The end station 104 may also include various beam sensors to sense the beam current density of the ion beam at various locations such as a beam sensor 118 upstream from the substrate 110 and a beam sensor 120 downstream from the substrate. As used herein, “upstream” and “downstream” are referenced in the direction of ion beam transport or the Z direction as defined by the X-Y-Z coordinate system of FIG. 1. Each beam sensor 118, 120 may contain a plurality of beam current sensors such as Faraday cups arranged to sense a beam current density distribution in a particular direction. The beam sensors 118, 120 may be driven in the X direction and placed in the beam line as needed.

Those skilled in the art will recognize that the ion beam etching system 100 may have additional components not shown in FIG. 1. For example, upstream of the substrate 110 there may be an extraction electrode that receives the ion beam from the ion beam generator 102 and accelerate the positively charged ions that form the beam, an analyzer magnet that receives the ion beam after positively charged ions have been extracted from the ion beam generator and accelerates and filters unwanted species from the beam, a mass slit that further limits the selection of species from the beam, electrostatic lenses that shape and focus the ion beam, and deceleration stages to manipulate the energy of the ion beam. Within the end station 104 it is possible that there are other sensors such as a beam angle sensor, charging sensor, wafer position sensor, wafer temperature sensor, local gas pressure sensor, residual gas analyzer (RGA), optical emission spectroscopy (OES), ionized species sensors such as a time of flight (TOF) sensor that may measure respective parameters.

The controller 106 may receive input data and instructions from any variety of systems and components of the ion beam etching system 100 and provide output signals to control the components of the system 100. The controller 106 can be or include a general-purpose computer or network of general-purpose computers that may be programmed to perform desired input/output functions. The controller 106 may include a processor 122 and memory 124. The processor 122 may include one or more processors known in the art. Memory 124 may include one or more computer-readable medium providing program code or computer instructions for use by or in connection with a computer system or any instruction execution system. For the purposes of this description, a computer readable medium can be any apparatus that can contain, store, communicate, propagate, or transport the program for use by or in connection with the computer, instruction execution system, apparatus, or device. The computer-readable medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include a compact disk-read only memory (CD-ROM), a compact disk-read/write (CD-R/W) and a digital video disc (DVD).

The controller 106 can also include other electronic circuitry or components, such as application specific integrated circuits, other hardwired or programmable electronic devices, discrete element circuits, etc. The controller 120 may also include communication devices.

A user interface system 126 may include, but not be limited to, devices such as touch screens, keyboards, user pointing devices, displays, printers, etc., to allow a user to input commands, data and/or to monitor the ion beam etching system 100 via the controller 106.

The controller 106 may be configured to allow a user to interact with the ion beam etching system 100. For example, the user can input a recipe for etching the substrate 110, view or modify a recipe that has been automatically selected by the controller 106 for etching the substrate. The recipe embodies characteristics that are desired to be on the substrate 110. In particular, the recipe would embody values for process parameters that the ion beam etching system 100 would use to produce a substrate with the desired characteristics. An illustrative but not exhaustive listing of process parameters includes vacuum chamber pressure, substrate temperature, ion beam species, energy, current, current density, ion to substrate angle, wafer scan velocity, beam scan velocity, end station pressure (or vacuum pumping speed), ion beam uniformity distribution. Additional parameters may include background pressure of one or more neutral gas species that may be supplied by one or more individually adjustable gas flow controllers, the gas species used to generate plasma for plasma etching, plasma density, neutral density in the plasma, electron temperature and degree of electron confinement.

The controller 106 uses the values of the process parameters from the recipe to select values for ion beam parameters that will be embodied in the ion beam used to etch the substrate 110. An illustrative but not exhaustive listing of ion beam parameters that the controller will set initial values for include ion beam intensity, ion beam current, angle that the ion beam strikes the surface, and dose rate of ions in the ion beam. In one embodiment, the controller 106 selects initial values for these ion beam parameters from a historical database that includes a number of entries that provide combinations of settings for these parameters as applied in past ion beam etchings. Typically, each entry has been compiled by receiving input data from various sources such as a recipe generator, a beam setup report, and an ion implant report.

The controller 106 also uses the values of the process parameters from the recipe to determine and control the application of atomic species applied by the ion beam generator 102 to the substrate 110 during the etching process. In one embodiment, the ion beam 108 generated by the ion beam generator 102 may be comprised of chemically inert species (Si+, Ar+, etc.) or additional chemical etching components (SiFx+, BF₂, etc.). In another embodiment, the ion beam generator 102 can also introduce reactive species to aid in attaining uniform etching of the substrate 110. Typical reactive species can include HCL, Cl₂, CO₂, CO, O₂, O₃, CF₄, NF₃, NF₂+ ions, BF₂+ ions, F ions, F+ ions, Cl or Cl+ ions. The reactive species may also include UV light either with or without a reactive gas. In another embodiment, the ion beam generator 102 may also introduce neutral reactive species or reactive low energy ions.

In operation, after the substrate 110 has been loaded and clamped to the platen 112, the ion beam generator 102 applies the atomic species to the surface of the substrate. The atomic species are reactive to the surface of the substrate 110. After the atomic species have interacted with the surface of the substrate 110 for a predetermined time, then the ion beam generator 102 directs the ion beam at the surface. The ion beam 108 strikes the surface of the substrate 110 causing the atomic species to volatize and initiate the etch. In essence, the ion beam controls the interaction that the atomic species has with the surface of the substrate 110 and facilitates a more uniform etch of the substrate.

In order to ensure that the ion beam 108 provides a uniform etch of the substrate 110, the controller 106 continually monitors the ion beam parameters (e.g., ion beam current, angle that the ion beam strikes the surface, and dose rate of ions in the ion beam). In particular, the controller receives measurements from beam sensors 118 and 120 and/or other sensors listed above. The received measurements take the form of signals that are indicative of ion beam properties that the controller uses to correlate to beam parameters such as ion beam current, angle that the ion beam strikes the surface, density of the ion beam and dose rate of ions in the ion beam.

The controller 106 then takes the values for the ion beam parameters and determines the etch depth and etch rate of the ion beam with respect to the substrate 110. In particular, the controller determines etch depth and etch rate by using any well known technique such as residual gas analysis (RGA), optical emission spectroscopy (OES) analysis of etch by products, surface analysis of the substrate by reflectometry, ellipsometry, interferometry, or other techniques. The etch depth and etch rate are used by the controller 106 to determine the uniformity of the etch. In particular, the local etch depth or local etch rate integrated in time provides a measurement of etch depth uniformity. In one embodiment, the etch depth and etch rate measurements provide a spatially resolved one or two dimensional etch profile distribution across the substrate.

If the controller 106 determines that the etch is not uniform spatially across the substrate, then the controller will adjust the ion beam generator 102 such that the ion beam 108 will contain values for the ion beam parameters (e.g., ion beam current, angle that the ion beam strikes the surface, density of the ion beam and dose rate of ions in the ion beam) that will lead to a more uniform etch of the substrate 110. For example, if the etch rate at the substrate edge were too low relative to the center, the ion beam current density (or dose rate) may be increased at the edge relative to the center in order to achieve uniform etch depth. This monitoring of the etching and adjusting of the ion beam continues until the etching of the substrate 110 has finished.

Although not shown in FIG. 1, the controller 106 can receive other measurements from sensors located within the end station 104, which can be used by the controller to control the uniformity of the etch. For example, controlling the temperature of the substrate permits adjusting of the adsorption rate and time of the atomic species as well as the reaction rate through the desorption of the species. Typically, temperature control of the substrate can be achieve through gas assisted cooling of the platen 112 or by cooling or heating the substrate 110. For example, it is possible through control of both backside gas pressure and the platen temperature to achieve a radial temperature distribution that may facilitate a more uniform etch profile.

Another parameter that the controller 106 may monitor and control and that can be used to provide a uniform etch is the dwell time of the atomic species on the substrate 110 prior to ion beam impact. In particular, the dwell time can alter the achieved reduction in sputtering energy as well as the local concentration and diffusion of the atomic species on the substrate 110. The dwell time is controlled by adjusting the physical configuration or spacing of the atomic species and the ion beam 108. The dwell time can also be controlled by adjusting the substrate scan velocity.

An additional parameter that the controller 106 may monitor and control and that can be use to provide a uniform etch is the substrate bias. Depending on the energy of the atomic species, the species can be adjusted to be negative or positive (e.g., −100 to 100 V).

Still another parameter that the controller 106 may monitor and control and that can be used to provide a uniform etch is the dose rate. In particular, does rate control permits adjusting of the instantaneous reaction rate to achieve the most efficient etch process. The energetic ion species dose rate is manipulated by changing the current density distribution within the ion beam, while the atomic species dose rate is manipulated by adjusting gas flow rates.

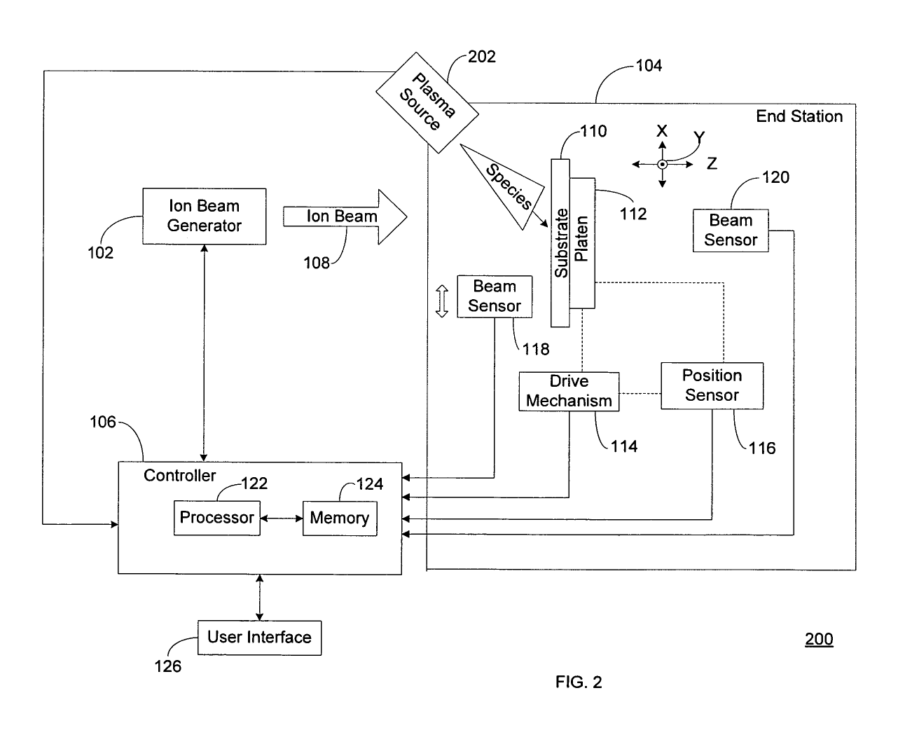

FIG. 2 shows a schematic block diagram of an ion beam etching system 200 according to a second embodiment of this disclosure. The ion beam etching system 200 is essentially the same as the system 100 shown in FIG. 1, however, the ion beam etching system of FIG. 2 includes a separate plasma source 202 for generating the atomic species. Instead, of having the ion beam generator 102 generate these species, the plasma source 202 is configured to generate atomic species such as the reactive species, inert species, metastable (electronically excited) species, neutral reactive species and/or reactive low energy ions. The plasma source 202 may be a line source, a multi-aperture source or another configuration that can provide a relatively uniform exposure to the substrate. Note that any electrical bias to the substrate 110 may be relative to the potential of the plasma source 202. In any event, the controlling and monitoring of the etching process as described for system 100 is applicable for this embodiment and therefore a separate discussion is not provided.

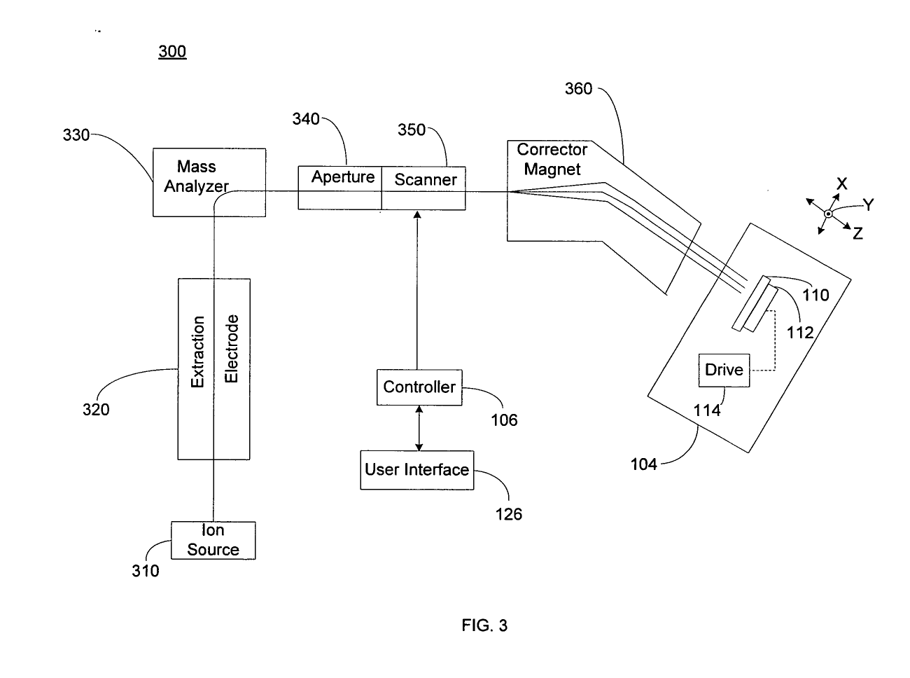

FIG. 3 shows a top view of a schematic block diagram of an ion implanter 300 that can be incorporated with the ion beam etching systems shown in FIGS. 1 and 2 according to one embodiment of the disclosure. Many other ion implanters will be known to those skilled in the art and the embodiment of FIG. 3 is provided by way of example only and is not intended to be limiting. The ion implanter 300 may include an ion source 310, an extraction electrode 320, a mass analyzer 330, a resolving aperture 340, a scanner 350, and an angle corrector magnet 360. Other components of FIG. 3 are similar to the components of FIGS. 1 and 2 and are similarly labeled and hence any repetitive description is omitted herein for clarity. For clarity of illustration, the controller 106 is illustrated as providing only an output signal to the scanner 350. Those skilled in the art will recognize that the controller 106 may provide output signals to each component of the ion implanter 300 and receive input signals from at least the same. In addition, although not shown in FIG. 3, the ion implanter 300 could have the plasma source 202 (FIG. 2) located about the end station 104.

The ion source 310 may generate ions and may include an ion chamber and a gas box containing a gas to be ionized. The gas may be supplied to the ion chamber where it is to be ionized. The ions thus formed may be extracted from the ion source 310. The extraction electrode 320 and an extraction power supply may accelerate ions from the ion source 310. The extraction power supply may be adjustable as controlled by the controller 106. The construction and operation of ion sources are well known to those skilled in the art.

The mass analyzer 330 may include a resolving magnet that deflects ions so that ions of a desired species pass through the resolving aperture 340 and undesired species do not pass through the resolving aperture 340. In one embodiment, the mass analyzer 330 may deflect ions of the desired species by 90 degrees. The scanner 350 positioned downstream from the resolving aperture 340 may include scanning electrodes as well as other electrodes for scanning the ion beam. The scanner 350 may include an electrostatic scanner or a magnetic scanner. Note that the scanner 350 is not required for other ion implanters using a ribbon beam. The angle corrector magnet 360 deflects ions of the desired ion species to convert a diverging ion beam to a nearly collimated ion beam having substantial parallel ion trajectories. In one embodiment, the angle corrector magnet 360 may deflect ions of the desired ion species by 70 degrees.

The scanner 350 may scan the ion beam in one direction and the drive mechanism 114 may physically drive the substrate 110 in a direction orthogonal to the scan direction to distribute the scanned ion beam 108 over the front surface of the substrate 110. In one example, the scan direction may be in the horizontal X direction while the drive mechanism 114 may drive the substrate vertically in the Y direction as those X and Y directions are defined by the coordinate system of FIG. 3.

Another ion implanter embodiment may generate a stationary or fixed spot beam (e.g., without a scanner) and the drive mechanism 114 may drive the substrate 110 in the X and Y directions to distribute the ion beam across the front surface of the substrate 110. Yet another ion implanter embodiment may generate a ribbon beam having a large width/height aspect ratio with a width at least as wide as the substrate 110. The drive mechanism 114 may then drive the substrate in a direction orthogonal to the width of the ribbon beam to distribute the ion beam across the front surface of the substrate 110.

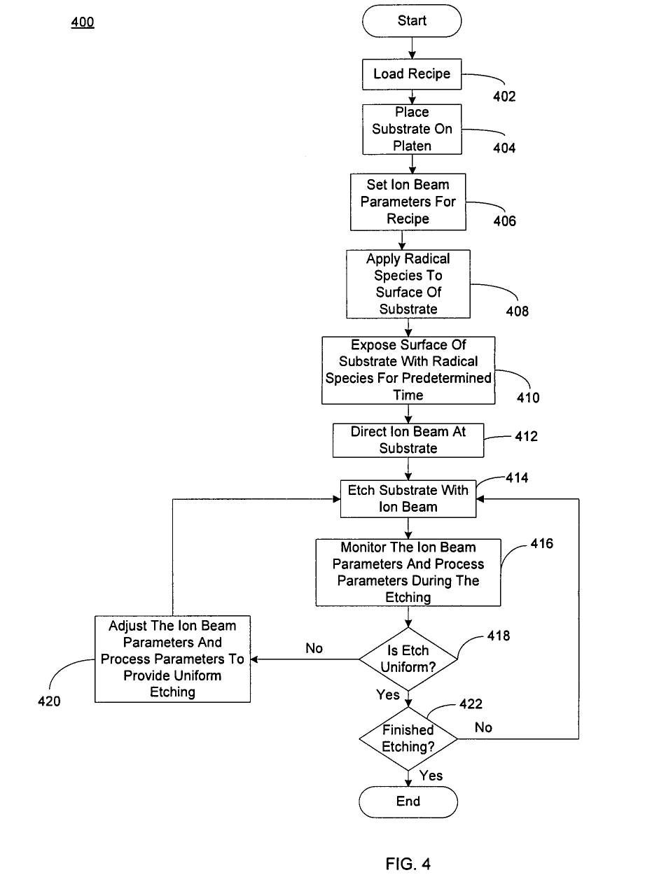

FIG. 4 shows a flow chart 400 describing the operation of the ion beam etching systems shown in FIGS. 1 and 2 according to one embodiment of this disclosure. The ion beam etching process begins at 402 where the recipe for the etch is loaded in or obtained by the ion beam etching system. As mentioned above, the recipe describes values for etch process parameters that the ion beam etching system will use to produce a substrate with the desired characteristics. After the recipe has been loaded, a substrate from a loading cassette or substrate holder is introduced into a vacuum chamber (within the end station) for processing. In particular, a transport mechanism places and locks the substrate in the vacuum chamber onto the platen at 404 in position where the ion beam and atomic species can penetrate the surface of the substrate.

The controller 106 uses the values of the etch process parameters from the recipe to select values for ion beam parameters at 406 that will be embodied in the ion beam used to etch the substrate 110. Afterwards, the controller initiates the application of the atomic species to the substrate 110 at 408. As mentioned above, the atomic species can include reactive species, chemically inert species, chemical etching components or reactive low energy ions. The atomic species interact with the surface of the substrate 110 for a predetermined time at 410.

The controller then prompts the ion beam generator 102 to direct the ion beam at the surface of the substrate at 412. The ion beam 108 strikes the surface of the substrate 110 causing the atomic species to volatize and initiate the etch at 414. The controller 106 continually monitors the ion beam parameters (e.g., ion beam current, angle that the ion beam strikes the surface, density of the ion beam and dose rate of ions in the ion beam) during the etching process at 416. In particular, the controller receives measurements from beam sensors 118 and 120 and determines at 418 whether the etch is uniform in the manner described above.

If the controller 106 determines at 418 that the etch is not uniform, then the controller will adjust the ion beam generator 102 at 420 such that the ion beam 108 will provide a more uniform etch of the substrate 110. The monitoring of the etching and adjusting of the ion beam embodied in blocks 414-418 continue until it has been determined at 422 that the etching of the substrate 110 has finished.

The foregoing flow chart shows some of the processing functions associated with controlling and monitoring the etching of a substrate with an ion beam assisted etching system. In this regard, each block represents a process act associated with performing these functions. It should also be noted that in some alternative implementations, the acts noted in the blocks may occur out of the order noted in the figure or, for example, may in fact be executed substantially concurrently or in the reverse order, depending upon the act involved. Also, one of ordinary skill in the art will recognize that additional blocks that describe the processing functions may be added.

It is apparent that there has been provided with this disclosure an approach that provides uniformity control for ion beam assisted etching. While the disclosure has been particularly shown and described in conjunction with a preferred embodiment thereof, it will be appreciated that variations and modifications will occur to those skilled in the art. Therefore, it is to be understood that the appended claims are intended to cover all such modifications and changes as fall within the true spirit of the invention.

What is claimed is:

1. A method for providing uniform etching in an ion beam based etch process, comprising:
providing a substrate;
directing an ion beam at a surface of the substrate;
etching the surface of the substrate with the ion beam; and
controlling the etching to attain uniformity in the etch of the substrate, wherein the controlling attains uniformity as a function of at least one ion beam based parameter selected from a plurality of ion beam based parameters.

2. The method according to claim 1, wherein the plurality of ion beam based parameters comprises ion beam intensity, ion beam current, angle that the ion beam strikes the surface and dose rate of ions in the ion beam.

3. The method according to claim 1, wherein the controlling attains uniformity further as a function of at least one etch process parameter selected from a plurality of etch process parameters.

4. The method according to claim 3, wherein the plurality of etch process parameters comprises substrate temperature, dwell time and substrate bias.

5. The method according to claim 1, wherein the controlling attains uniformity by controlling the at least one ion based parameter spatially across the substrate.

6. The method according to claim 1, further comprising applying atomic species to the surface of the substrate prior to directing the ion beam at the surface.

7. The method according to claim 1, further comprising monitoring the etching of the substrate according to the at least one ion beam based parameter.

8. The method according to claim 7, wherein the monitoring comprises obtaining measurements during the etching that relate to the at least one ion beam based parameter.

9. The method according to claim 7, further comprising adjusting the etching of the substrate as a function of the monitoring of the at least one ion beam based parameter, wherein the adjusting continues until the etching becomes uniform.

10. An ion beam etching system, comprising:
an end station configured to receive a substrate for ion beam etching;
an ion beam generator configured to direct an ion beam into the end station onto the substrate for etching thereof; and
a controller configured to ensure that the ion beam generator provides uniform etching of the substrate, wherein the controller provides uniform etching as a function of at least one ion beam based parameter selected from a plurality of ion beam based parameters.

11. The system according to claim 10, wherein the plurality of ion beam based parameters comprise ion beam intensity, ion beam current, angle that the ion beam strikes the surface, density of the ion beam and dose rate of ions in the ion beam.

12. The system according to claim 10, wherein the controller provides uniform etching further as a function of at least one etch process parameter selected from a plurality of etch process parameters.

13. The system according to claim 12, wherein the plurality of etch process parameter comprises substrate temperature, dwell time and substrate bias.

14. The system according to claim 10, wherein the controller attains uniformity by controlling the at least one ion based parameter spatially across the substrate.

15. The system according to claim 10, further comprising a plasma source configured to apply atomic species to the surface of the substrate prior to the ion beam generator directing the ion beam at the surface of the substrate.

16. The system according to claim 10, wherein the controller is further configured to monitor the etching of the substrate according to the at least one ion beam based parameter.

17. The system according to claim 16, wherein the controller is configured to obtain measurements from the end station during the etching that relate to the at least one ion beam based parameter.

18. The system according to claim 17, wherein the controller is configured to adjust the etching of the substrate as a function of the measurements until the etching becomes uniform.

19. A computer-readable medium storing computer instructions, which when executed by a computer system enables an ion beam etching system to provide uniformity in the etching of a substrate, the computer instructions comprising:
obtaining measurements during the etching of the substrate that relate to at least one ion beam based parameter selected from a plurality of ion beam based parameters;
determining whether the measurements are indicative of a uniform etch spatially across the substrate; and
adjusting the at least one ion beam based parameter in response to a determination that the measurements are indicative of a non-uniform etch.

20. The computer-readable medium according to claim 19, further comprising instructions for obtaining measurements during the etching of the substrate that relate to at least one etch process parameter selected from a plurality of etch process parameters.

21. The computer-readable medium according to claim 20, wherein the plurality of etch process parameter comprises substrate temperature, dwell time and substrate bias.

22. The computer-readable medium according to claim 19, further comprising instructions for continuing the ion beam etching of the substrate in response to a determination that the measurements are indicative of a uniform etch.

23. The computer-readable medium according to claim 19, wherein the plurality of ion beam based parameters comprise ion beam intensity, ion beam current, angle that the ion beam strikes the surface, density of the ion beam and dose rate of ions in the ion beam.
